(19) United States
(12) Patent Application Publication
(10) Pub. No.: US 2025/0268039 A1
(43) Pub. Date: Aug. 21, 2025

(54) ELECTRONIC DEVICE

(71) Applicant: Samsung Display Co., Ltd., Yongin-Si (KR)

(72) Inventors: EUI JEONG KANG, Yongin-si (KR); SUJEONG KIM, Yongin-si (KR); CHANGWOO WON, Yongin-si (KR); SEOUNGBUM PYOUN, Yongin-si (KR)

(21) Appl. No.: 19/012,853

(22) Filed: Jan. 8, 2025

(30) Foreign Application Priority Data
Feb. 20, 2024 (KR) 10-2024-0024553

(51) Int. Cl. H10K 59/131; H10K 59/88

(52) U.S. Cl. CPC H10K 59/131; H10K 59/88

(57) ABSTRACT

An electronic device includes a display panel including pads arranged along a first direction, and a circuit board facing the display panel in a second direction intersecting the first direction and including a wiring board electrically connected to the pads and an electronic component mounted on the wiring board. The wiring board includes a body part that has a first thickness and on which the electronic component is mounted, and a protrusion part that has a second thickness smaller than the first thickness and protrudes from the body part toward the display panel, of which at least a portion overlaps the display panel, and which provides a terminal part connected to the pads. At least one notch is defined on a side of the wiring board facing the display panel.

### CROSS-REFERENCE TO RELATED APPLICATIONS

This application claims priority under 35 U.S.C. § 119 to Korean Patent Application No. 10-2024-0024553 filed on Feb. 20, 2024, in the Korean Intellectual Property Office, the disclosures of which are incorporated by reference herein in their entireties.

### BACKGROUND

Embodiments of the present disclosure relate to electronic devices and more particularly to electronic devices that are thinner or that have a smaller bezel.

Current electronic devices commonly display images or sense external inputs. Such electronic devices typically include a circuit board on which various electronic components are mounted. As electronic devices that display high-resolution images or include various functions have been developed, the complexity of the various electronic components and signal wirings has increased, and thus the size and costs of the circuit boards in such electronic devices have increased. Further, larger circuit boards and bendable circuit boards when assembled have required electronic devices to be thicker.

### SUMMARY

Embodiments of the present disclosure provide an electronic device with a bezel and a thickness that are reduced and provide a process that reduces the costs needed to produce an electronic device.

According to an embodiment, an electronic device includes a display panel including pads arranged along a first direction, a circuit board facing the display panel in a second direction crossing the first direction and including a wiring board electrically connected to the pads, and an electronic component mounted on the wiring board. The wiring board includes a body part that has a first thickness and on which the electronic component is mounted, and a protrusion part that has a second thickness smaller than the first thickness and protrudes from the body part toward the display panel. At least a portion of the protrusion part overlaps the display panel, and the protrusion part provides a terminal part connected to the pads. At least one notch may be on a side of the wiring board facing the display panel.

The notch may be in an area adjacent to the protrusion part on the side of the body part facing the display panel.

The notch may be on the side of the protrusion part facing the display panel.

A plurality of the protrusion parts may be arranged along the first direction, and the notch may be defined between the protrusion parts on a side of the body part facing the display panel.

The body part may include two cover layers having insulating properties, at least one first insulating layer disposed between the two cover layers, at least one second insulating layer disposed between the two cover layers and being more flexible than the first insulating layer, at least one wiring layer disposed between the two cover layers and being conductive, and a via layer that passes through at least one of the first insulating layer and the second insulating layer and electrically connects the at least one wiring layer and the electronic component and the terminal part, and the protrusion part may be formed by removing a portion of at least one of the components of the body part.

The protrusion part may include a single wiring layer, and the single wiring layer may extend from one of the wiring layers of the body part.

The first insulating layer may include a film.

The second insulating layer may include a prepreg.

The protrusion part may further include a step portion having a thickness that is smaller than the first thickness and different from the second thickness, and the step portion may be disposed between the body part and a portion having the first thickness in the second direction.

The step portion may have a shape integrated with the portion having the first thickness.

The circuit board may further include a dummy terminal part disposed in the protrusion part and electrically insulated from the terminal part, and the dummy terminal part may be disposed more adjacent to an outer side of the protrusion part than the terminal part in the first direction.

The dummy terminal part may have a shape inclined in the first direction and the second direction.

The electronic device may further include a case that provides a space to accommodate the circuit board, and the space may extend from the display panel in the second direction.

According to an embodiment, an electronic device includes a display panel including pads arranged along a first direction, and a circuit board facing the display panel in a second direction crossing the first direction and including a wiring board including a terminal part connected to the pads and an electronic component mounted on the wiring board. The wiring board may include a body part including a plurality of wiring layers, at least one of the wiring layers being connected to the electronic component, and a protrusion part having a shape integrated with the body part and including a single wiring layer extending from any one of the wiring layers. A first notch recessed in a direction away from the display panel between the body part and the protrusion part may be on a side of the wiring board that faces the display panel.

The protrusion part may include a first portion having a first thickness, and a second portion having a thickness greater than the first portion and disposed between the first portion and the body part in the second direction, and the first portion may have a shape integrated with at least a portion of the second portion.

A length of the second portion in the second direction may correspond to a recessed depth of the first notch.

The circuit board may further include a dummy terminal part disposed in the protrusion part and electrically insulated from the terminal part, and the dummy terminal part may be disposed between the first notch and the terminal part in the first direction.

The terminal part may extend in a direction inclined in the first direction and the second direction.

The circuit board may further include a second notch defined on a side of the protrusion part that faces the display panel.

A plurality of the protrusion parts may be arranged along the first direction, and the circuit board may further include a third notch defined in the body part and disposed between the plurality of protrusion parts.

### BRIEF DESCRIPTION OF THE DRAWINGS

The above and other objects and features of the present disclosure will become apparent by describing in detail embodiments thereof with reference to the accompanying drawings.

FIG. 1A is a perspective view of a coupled state of a display device according to an embodiment of the present disclosure.

FIG. 1B is an exploded perspective view of the display device according to an embodiment of the present disclosure.

FIG. 2A is a plan view of a display module according to an embodiment of the present disclosure.

FIG. 2B is an exploded plan view of the display module of FIG. 2A.

FIG. 3 is a cross-sectional view of an electronic device according to an embodiment of the present disclosure.

FIG. 4 shows cross-sectional views of an electronic device according to an embodiment of the present disclosure and an electronic device according to a comparative embodiment.

FIG. 5 is a plan view of a circuit board according to an embodiment of the present disclosure.

FIGS. 6A, 6B, and 6C are cross-sectional views of a circuit board according to an embodiment of the present disclosure.

FIGS. 7A, 7B, and 7C are cross-sectional views of a circuit board according to an embodiment of the present disclosure.

FIGS. 8A and 8B are cross-sectional views of a circuit board according to an embodiment of the present disclosure.

FIGS. 9A and 9B are cross-sectional views of display modules according to an embodiment of the present disclosure.

FIGS. 10A, 10B, 10C, and 10D are plan views illustrating a portion of the circuit board according to some embodiments of the present disclosure.

FIGS. 11A and 11B are plan views illustrating partial areas of the display module according to some embodiments of the present disclosure.

### DETAILED DESCRIPTION

In the specification, a first component (or an area, a layer, a part, a portion, etc.) being “disposed on”, “connected with” or “coupled to” a second component means that the first component may be directly disposed on/connected with/coupled to the second component or that a third component may be interposed therebetween.

The same reference numerals in the various drawings refer to the same or corresponding components. Further, in the drawings, the thicknesses, the ratios, and other dimensions of components may be exaggerated or otherwise altered for effective illustration or description of technical contents.

The term “and/or” includes all combinations of one or more components that may be defined by associated configurations.

Although descriptions of various components may use the terms “first”, “second”, etc., the components should not be limited by these terms. The terms are only used to distinguish one component from another component. For example, without departing from the scope of the present disclosure, a first component may be referred to as a second component, and similarly, the second component may be referred to as the first component.

The terms “under”, “beneath”, “on”, “above”, etc. are used to herein describe a relative relationship of components illustrated in the drawings. The terms that are relative in concept are described based on a direction illustrated in drawings.

Unless otherwise defined, all terms (including technical terms and scientific terms) used in the specification have the meaning as commonly understood by those skilled in the art to which the present disclosure belongs. Further, terms defined in commonly used dictionaries should be construed as having the same meanings as those in the context of the related art and may be explicitly defined therein unless the terms are interpreted in an ideal or excessive formal meaning. Singular expressions as used herein include plural expressions unless the context clearly indicates otherwise.

The terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Hereinafter, example embodiments of the present disclosure are described with reference to the accompanying drawings.

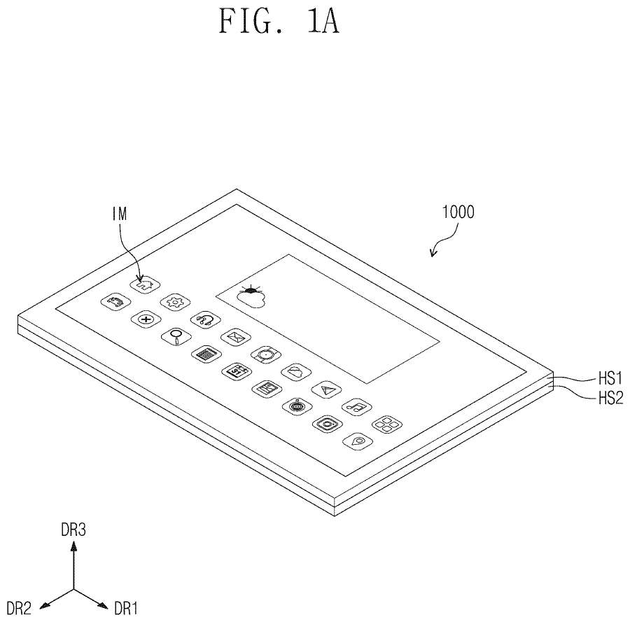

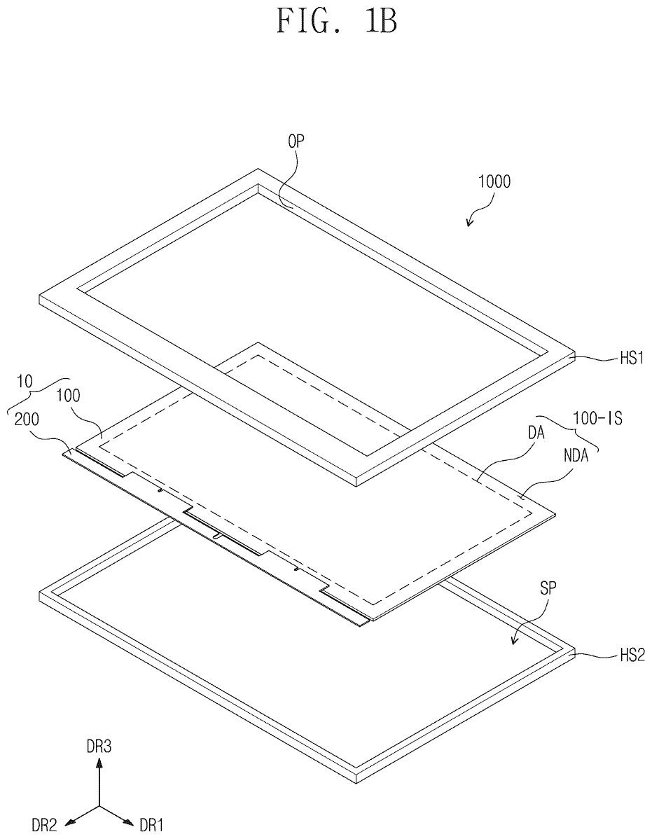

FIG. 1A is a perspective view of an assembled state of an electronic device 1000 according to an embodiment of the present disclosure, and FIG. 1B is an exploded perspective view of the electronic device 1000.

The electronic device 1000 may be a display device that provides an image IM to a user. The image IM may include a still image or a moving image. The electronic device 1000 may include at least one display surface on which an image IM is displayed. The user may obtain information or operate the electronic device 1000 through the image IM.

The electronic device 1000 may be or may be used in a portable electronic device such as a mobile phone, smartphone, tablet personal computer (PC), mobile communication terminal, electronic notebook, e-book, portable multimedia player (PMP), navigation system, and ultra mobile PC (UMPC). Alternatively, the electronic device 1000 may be or may be used in a larger device such as a television (TV), laptop, monitor, billboards, Internet of Things (IoT), or the like. According to an embodiment, the electronic device 1000 may also be used in a wearable device such as a smart watch, watch phone, glasses-type display, or head mounted display (HMD). According to an embodiment, the electronic device 1000 may also be used in a dashboard of a vehicle, center information display (CID) on the center fascia or dashboard of a vehicle, a mirror display that replace a side view mirror of a vehicle, and display screen arranged on the rear side of a seat to serve as an entertainment device for back seat passengers in a vehicle.

The electronic device 1000 may include a display module 10, an upper cover HS1, and a lower cover HS2. The display module 10 may include a display panel 100 and a circuit board 200 that are electrically connected to each other.

The display panel 100 may have a front surface 100-IS, and the front surface 100-IS may include a display area DA and a peripheral area NDA. The display area DA may be a substantial area on which the image IM is displayed, and the peripheral area NDA may be an area on which the image IM is not displayed. The peripheral area NDA may be an area adjacent to the display area DA. In the illustrated embodiment, the peripheral area NDA has a frame shape surrounding an edge of the display area DA, but the planar shape of the peripheral area NDA is not limited thereto.

The upper cover HS1 may be disposed on the display panel 100 to protect the display panel 100. The upper cover HS1 has an opening OP through which at least a portion of the front surface 100-IS is visible. The opening OP may have a size at least corresponding to the display area DA. The opening OP may overlap the display area DA, and the image IM displayed on the display area DA may be visually recognized from the outside through the opening OP.

The lower cover HS2 is disposed under the display panel 100 to protect the display panel 100. The lower cover HS2 may provide an accommodation space SP, and the display panel 100 may be accommodated in the accommodation space SP. The lower cover HS2 may be coupled to the upper cover HS1 to form an exterior of the electronic device 1000. However, FIGS. 1A and 1B only schematically illustrate the electronic device 1000, and the electronic device 1000 may further include other components such as a power device such as a battery, other electronic components, or an additional protective member surrounding the upper cover HS1 and the lower cover HS2, but the present disclosure is not limited to an embodiment.

The display panel 100 and the circuit board 200 may be accommodated in the internal space SP in a flat or an unfolded state. That is, the display panel 100 and the circuit board 200 when assembled in the electronic device 1000 may be parallel to a plane defined by a first direction DR1 and a second direction DR2. A portion of the circuit board 200, except for a portion connected to the non-display area NDA of the display panel 100, does not overlap the display panel 100 in the plan view when the electronic device 1000 is assembled. Accordingly, the upper cover HS1 may cover not only the peripheral area NDA of the display panel 100 but also the entire circuit board 200.

According to an aspect of the present disclosure, the circuit board 200 may not provide a separate folding area for folding, e.g., for bending to position a portion of the circuit board beneath the display panel 100. Accordingly, a separate flexible film connecting the circuit board 200 and the display panel 100 may be omitted, and thus costs of the electronic device 1000 may be reduced, and an assembly process may be simplified.

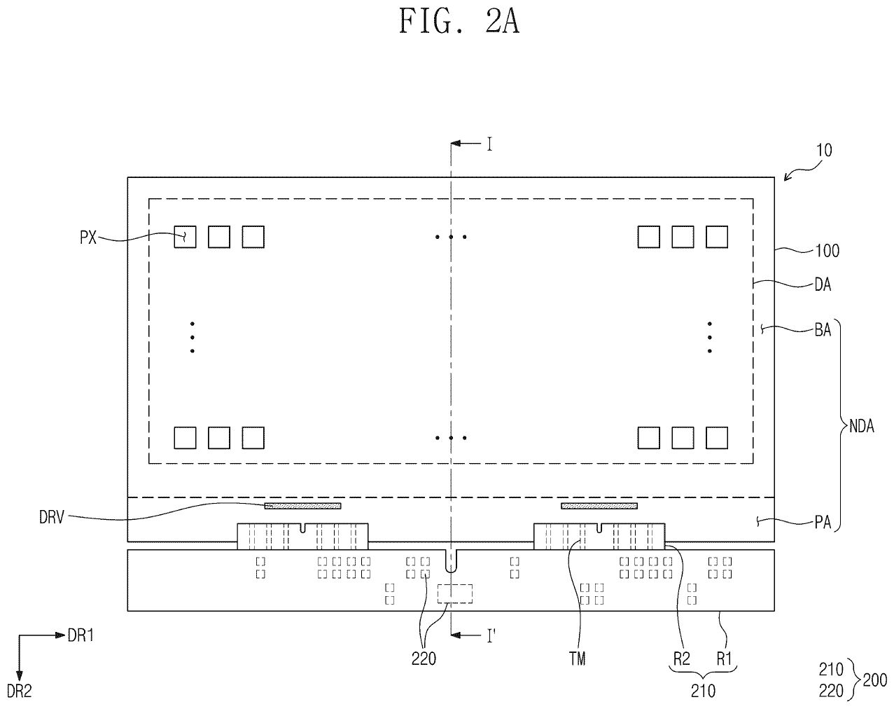

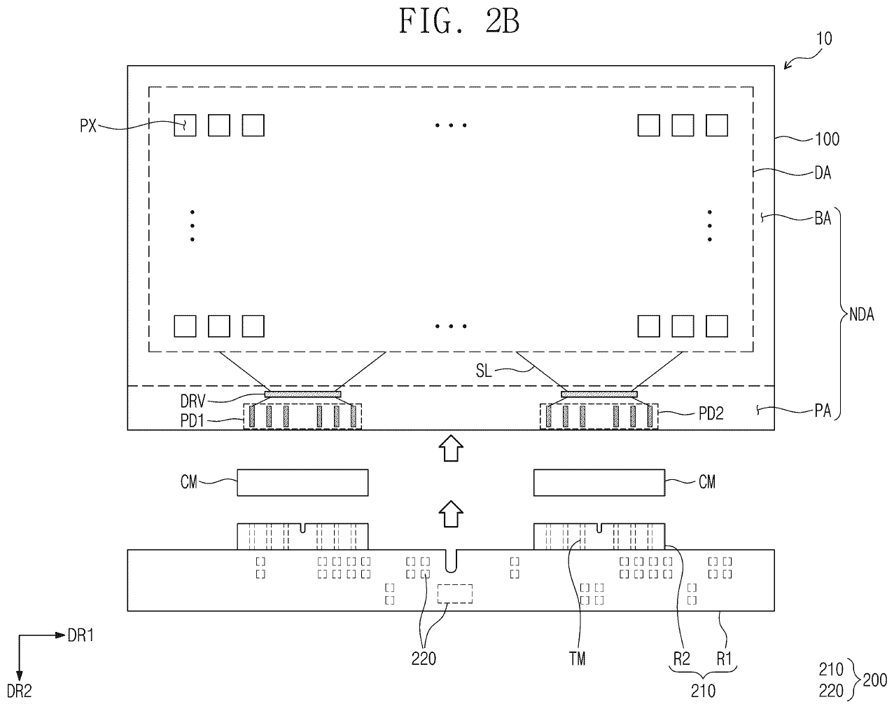

FIG. 2A is a plan view of a display module according to an embodiment of the present disclosure. FIG. 2B is an exploded plan view of the display module of FIG. 2A. The present disclosure will be described with reference to FIGS. 2A and 2B.

FIGS. 2A and 2B particularly illustrate an embodiment of the display module 10 that may be formed by physically and electrically coupling the display panel 100, the circuit board 200, and a connection member CM.

The display panel 100 may include a plurality of pixels PX. Each of the pixels PX may emit light or otherwise display a color. The emitted light or colors displayed by the pixels PX constitute the image IM.

The area of the display panel 100 may include the display area DA, the peripheral area NDA, and a pad area PA. As described above, the display area DA may be an area on which an image is displayed. The plurality of pixels PX that form an image may be arranged in the display area DA. In detail, components of the pixels PX that generate or display light may be arranged in the display area DA. The pixels PX may be arranged in a matrix having columns and rows that respectively extend in the second direction DR2 and the first direction DR1. The display panel 100 controls the pixels PX to display various images. Each of the pixels PX may include a display element and a driving element.

Many types of display elements may be included in various embodiments of the pixels PX. For example, each display element may be at least one of a liquid crystal capacitor, an organic light emitting element, an electrophoretic element, and an electrowetting element. However, these are just a few examples, and the display element in each pixel PX may include any suitable structure capable of implementing an image according to an electrical signal, and the present disclosure is not limited to any specific embodiment of display element. The driving element drives the display element in each of the pixels PX. The driving element may include one or more thin film transistors. The display panel 100 according to an embodiment of the present disclosure may be driven in an active manner in which the pixels PX may be independently controlled.

The peripheral area NDA is adjacent to the display area DA. Signal wirings connected to the pixels PX may be arranged in the peripheral area NDA. The peripheral area NDA may include an edge area BA and the pad area PA. In an embodiment, the edge area BA may have a frame shape surrounding the display area DA. However, this is just one example, and the edge area BA may have various shapes as long as the edge area BA is adjacent to the display area DA, and the present disclosure is not limited to the illustrated embodiment.

The pad area PA may be spaced apart from the display area DA and adjacent to the edge area BA. In the embodiment illustrated in FIGS. 2A and 2B, the pad area PA is spaced apart from the display area DA in the second direction DR2, but the present disclosure is not limited thereto. The pad area PA may be defined in an area spaced apart from the display area DA in the first direction DR1 or may be defined in both areas, and the present disclosure is not limited to these examples.

The pad area PA may be an area coupled to the circuit board 200. In the illustrated embodiment, two pad parts PD1 and PD2 are provided in the pad area PA, but the number of pad parts is not limited thereto. Each of the pad parts PD1 and PD2 may include a plurality of pads for electrical connection to the circuit board 200.

The circuit board 200 at least partially overlaps the pad area PA. The circuit board 200 may provide image data, a control signal, a power voltage, and the like to the display panel 100. The display panel 100 may be capable of sensing an external input such as a touch, a pen, or light applied from the outside, and the circuit board 200 may provide to the display panel 100 a driving signal for sensing the external input.

The circuit board 200 may be physically and electrically connected to the display panel 100. The circuit board 200 may include a wiring board 210 and a plurality of electronic components 220 mounted thereon.

The wiring board 210 may be a printed circuit board PCB and may be rigid. The wiring board 210 may include at least one insulating layer and at least one wiring layer. The electronic components may be connected to the wiring layer and electrically connected to each other. A part of the wiring layer may be a terminal part TM. The terminal part TM is connected to a corresponding pad among the pads.

The electronic components 220 may include active elements and passive elements. In detail, the electronic components 220 may include a chip-related component, a network-related component, and other components.

The chip-related component may include at least one of a memory, a processor, and a logic circuit. For example, the memory may include a volatile memory, a non-volatile memory, a flash memory or the like. For example, the processor may include an application processor such as a graphic processing unit (GPU), a central processing unit (CPU), a digital signal processor, a cryptographic processor, a microprocessor, or a micro-controller. Further, for example, the logic circuit may include a non-memory semiconductor such as an analog-to-digital converter (ADC) and an application-specific integrated circuit (ASIC). The chip-related component may be provided in a chip form or a package form.

The network-related component may comply with a wireless protocol and/or a wired protocol. The other component may include an inductor, an electromagnetic interference (EMI) filter, or the like.

A connection member CM is disposed in the pad area PA. The connection member CM electrically connects the circuit board 200 and the display panel 100. The connection member CM may have electrical conductivity and adhesiveness. The connection member CM may include a thermosetting or photocuring material. For example, the connection member CM may include an anisotropic conductive film ACF.

In an embodiment, the terminal part TM of the circuit board 20 may be connected to the pad parts PD1 and PD2 of the display panel 100. As the circuit board 200, including various electronic components 220, is directly connected to the display panel 100, a separate flexible film or wiring film for connecting the circuit board 200 and the display panel 100 may be omitted. Accordingly, process costs may be reduced, and the assembly process may be simplified.

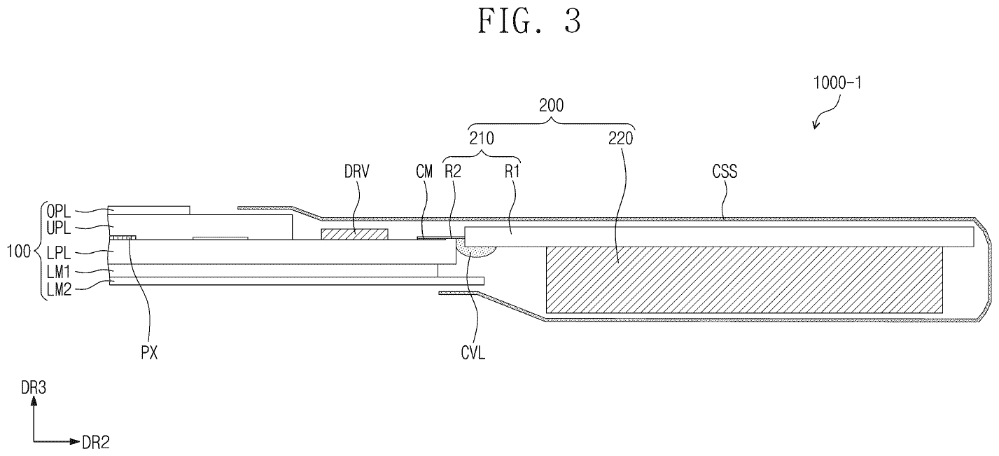

FIG. 3 is a cross-sectional view of an electronic device according to an embodiment of the present disclosure. FIG. 3 particularly shows a cross-sectional view of an electronic device 1000-1 employing a case CSS.

At least a portion of the display module 10 may be inserted into and protected by the case CSS. In an embodiment, the case CSS may provide a space in which the circuit board 200 among the components of the display module 10 is accommodated and may stably protect the circuit board 200.

The display panel 100 may include a first lower member LM1, a second lower member LM2, a lower substrate LPL, an upper substrate UPL, and an optical layer OPL that are stacked and laminated in a third direction DR3 as shown in FIG. 3.

Each of the first lower member LM1 and the second lower member LM2 may include components that protect the display panel 100 or improve reliability. For example, each of the first lower member LM1 and the second lower member LM2 may include a light shielding film, a heat dissipating member, an impact absorbing member, a support member, a shielding member or the like, but embodiments in accordance with the present disclosure are not limited thereto. Further, each of the first lower member LM1 and the second lower member LM2 may include a separate functional member. For example, each of the first lower member LM1 and the second lower member LM2 may include a touch sensor, an optical sensor, a digitizer, a pressure sensor, a battery, or the like, but embodiments in accordance with the present disclosure are not limited thereto.

The lower substrate LPL may be a base layer on which the pixels PX are arranged. The lower substrate LPL may be a single layer or may include a plurality of insulating layers. The lower substrate LPL may be at least one of a glass substrate, a plastic substrate, a film, and a laminate including a plurality of organic films and/or inorganic films, but embodiments in accordance with the present disclosure are not limited thereto.

Each of the pixels PX may include a driving circuit and a display element that are electrically connected to each other. The driving circuit may include at least one transistor. For example, the driving circuit may include at least one transistor and a capacitor. Although not shown in FIG. 3, the lower substrate LPL may include signal wirings or the like connecting the pixels PX. Accordingly, the lower substrate LPL may include a laminated structure including a plurality of conductive layers and a plurality of organic films and/or inorganic films.

Each display element displays a light. For example, when the display panel 100 is an organic light emitting display panel, each of the pixels PX may include an organic light emitting element as the display element. The present disclosure is not limited thereto, and the display element may take various forms such as a liquid crystal capacitor, a light emitting diode (LED), an n-LED, an m-LED, a quantum dot light emitting element, an electrowetting element, and an electrophoresis element or any form capable of displaying light according to an electrical signal received from the driving circuit, but embodiments in accordance with the present disclosure are not limited thereto.

The upper substrate UPL may be disposed on the lower substrate LPL and covers the pixels PX. The upper substrate UPL may protect the pixels PX. The upper substrate UPL may include at least one of an encapsulation layer, an encapsulation substrate, and a window. When the upper substrate UPL includes an encapsulation layer, the upper substrate UPL may have a laminated structure in which at least one inorganic film and at least one organic film are stacked and laminated. When the upper substrate UPL includes an encapsulation substrate or a window, the upper substrate UPL may include glass or plastic. The upper substrate UPL may further include a touch sensor or a digitizer. In this case, the display panel 100 may be a touch screen panel that may display an image and sense an external input. Alternatively, the touch sensor or the digitizer may be disposed on the lower substrate LPL or disposed under the lower substrate LPL, but embodiments in accordance with the present disclosure are not limited thereto.

The optical layer OPL may be disposed on the upper substrate UPL. The optical layer OPL may improve display characteristics of an image that the display panel 100 forms. For example, the optical layer OPL may include a reflection preventing layer, a color filter, a polarizing film, or a fingerprint preventing layer. Alternatively or additionally, the optical layer OPL may include a protective film or a protective layer that protects the upper substrate UPL. In the display panel 100 according to an embodiment, the optical layer OPL may be omitted or provided integrally with the upper substrate UPL, but embodiments of the present disclosure are not limited thereto.

The circuit board 200 may include the wiring board 210 and the electronic component 220. The circuit board 200 may be accommodated in the case CSS. The case CSS may be made of a material, such as a metal, an alloy, or plastic, having higher rigidity than the circuit board 200. The case CSS may have a shape that surrounds the circuit board 200 and may protect the circuit board 200 from an external impact or the like. In the illustrated embodiment, the case CSS covers not only the circuit board 200 but also a driving unit DRV of the display panel 100. Accordingly, the case CSS may stably protect not only the circuit board 200 but also the driving unit DRV. Alternatively, the case CSS may be omitted, and embodiments in accordance with the present disclosure are not limited to embodiments including the case CSS.

The wiring board 210 may include a body part R1 and a protrusion part R2. The body part R1 may be a part on which the electronic component 220 is mounted. The body part R1 may include a plurality of conductive layers. The conductive layer may be a wiring layer including various signal wirings electrically connected to the electronic component 220. A detailed description thereof is provided below.

The protrusion part R2 may overlap and connect to the display panel 100. The connection member CM may facilitate physical/electrical coupling between the protrusion part R2 and the display panel 100. The protrusion part R2 may have a thickness that is smaller than a thickness of the body part R1. The protrusion part R2 may be formed by removing or omitting at least a portion of the structure of the body part R1. The protrusion part R2 may include at least the terminal part TM (see FIG. 2B). The terminal part TM may be coupled to the pad parts PD1 and PD2 (see FIG. 2B) of the display panel 100 and thus electrically connected to the display panel 100.

The terminal part TM may extend from any one of the conductive layers of the body part R1. The display panel 100 may be electrically connected to the circuit board 200 through the terminal part TM and may be electrically connected to the electronic component 220 through signal wirings in the body part R1.

The protrusion part R2 may include a single conductive layer (or a wiring layer). In particular, in the circuit board 200, the body part R1 may include a plurality of wiring layers and the protrusion part R2 may include a single wiring layer. The single wiring layer in the protrusion part R2 may be a layer that provides the terminal part TM. A detailed description thereof is provided below.

The electronic component 220 may be mounted on the body part R1. The body part R1 may have a relatively large size/area and great rigidity as compared to the protrusion part R2. The body part R1 may be more rigid than the protrusion part R2. Accordingly, the electronic component 220 may be stably mounted on the body part R1.

The electronic device 1000-1 in the embodiment of FIG. 3 may further include a cover layer CVL. The cover layer CVL may be disposed between the protrusion part R2 and the body part R1 and may be in contact with a side surface of the lower substrate LPL. The cover layer CVL may be a coating layer formed from a liquid that is cured, but the present disclosure is not limited thereto. The cover layer CVL may prevent bending of the protrusion part R2 or prevent separation of the connection between the protrusion part R2 and the display panel 100.

As illustrated in FIG. 3, in the electronic device 1000-1 according to an embodiment of the present disclosure, the circuit board 200 may be assembled in a state in which the circuit board 200 defines the same plane as the display panel 100 without bending. The case CSS may be coupled to the display panel 100 to keep the display panel 100 and the circuit board 200 coplanar, prevent sagging of the circuit board 200, or the like. The electronic device 1000-1 includes the circuit board 200, which is assembled without bending, and thus the electronic device 1000-1 may have a reduced thickness when compared to an electronic device in which the display panel 100 and the circuit board 200 are not coplanar. In the electronic device 1000-1, a width in the second direction DR2 of the protrusion part R2 connected to the display panel 100 may be minimized, the protrusion part R2 connected to the display panel 100 and the body part R1 on which the electronic component 220 is mounted may be simultaneously provided through a single printed circuit board, and thus material costs for manufacturing may be reduced, and the degree of freedom of design may be improved.

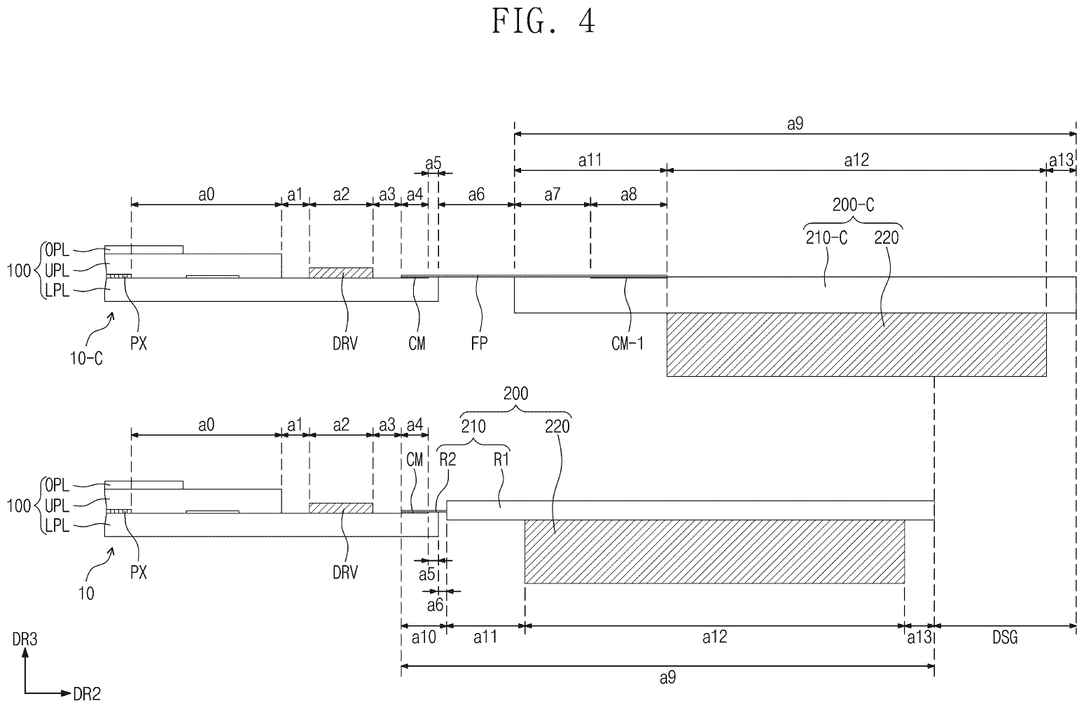

FIG. 4 shows cross-sectional views of an electronic device according to an embodiment of the present disclosure and an electronic device according to a comparative embodiment. For easy description, FIG. 4 illustrates the display modules 10 and 10-C of the electronic device 1000-1 (see FIG. 3) except for the case CSS (see FIG. 3) and illustrates the display panel 100 including the lower substrate LPL, the upper substrate UPL, and the optical layer OPL and the circuit boards 200 and 200-C connected thereto.

As illustrated in FIG. 4, the display module 10 according to an embodiment of the present disclosure may include the display panel 100 and the circuit board 200. The display module 10 illustrated in FIG. 4 may substantially correspond to the components of the display module 10 illustrated in FIG. 3, and thus a duplicated description thereof is omitted here.

The display module 10-C according to the comparative embodiment may include the display panel 100, a circuit board 200-C, and a flexible film FP. The circuit board 200-C may include a wiring board 210-C and the electronic component 220. That is, the display module 10-C according to an embodiment may further include the flexible film FP when compared to the display module 10 in accordance with an embodiment of the present disclosure. The flexible film FP may be relatively flexible as compared to the wiring board 210-C. The flexible film FP may be an insulating film on which a wiring layer is mounted and may be, for example, a tape carrier package (TCP) or a chip-on-film (COF) structure. A film connecting member CM-1 for electrical coupling between the flexible film FP and the wiring board 210-C may be further included, and the film connecting member CM-1 may be, for example, an anisotropic conductive film (ACF).

A size of a lower end portion of the display panel 100 of the display module 10 may be the same as a size of a lower end portion of the display panel 100 of the comparative display module 10-C based on a width in the second direction DR2 of the display modules 10 and the comparative display module 10-C. That is, a distance a0 (hereinafter, referred to as a zero distance) between the pixels PX and a distal end of the upper substrate UPL, a distance a1 (hereinafter, referred to as a first distance) between the distal end of the upper substrate UPL and the driving unit DRV, a width a2 (hereinafter, referred to as a second distance) of the driving unit DRV, a distance a3 (hereinafter, referred to as a third distance) between a distal end of the driving unit DRV and the connection member CM, a width a4 (hereinafter, referred to as a fourth distance) of the connection member CM, and a distance a5 (hereinafter, referred to as a fifth distance) between a distal end of the connection member CM and a distal end of the lower substrate LPL, which are measured in the second direction DR2, may be substantially the same in the display module 10 according to an embodiment and the comparative display module 10-C. Here, the connection member CM may substantially correspond to an area in which the pad parts PD1 and PD2 of the display panel 100 are arranged. Accordingly, the third distance a3 may correspond to a gap between the driving unit DRV and the pad parts PD1 and PD2, the fourth distance a4 may substantially correspond to a length of the pad parts PD1 and PD2 in the second direction DR2, and the fifth distance a5 may correspond to a gap between the pad parts PD1 and PD2 and the distal end of the lower substrate LPL. The zero distance a0 and the first to fifth distances a1, a2, a3, a4, and a5 may have numerical values that determine the size of the lower end of the display panel 100 and may have numerical values that are determined through design of the display panel 100. Thus, the zero distance a0 and the first to fifth distances a1, a2, a3, a4, and a5 may have numerical values that are not affected by differences between the connected circuit boards 200 and 200-C.

The distance in the second direction DR2 between distal ends of the circuit boards 200 and 200-C from a distal end of the display panel 100 may differ from each other, causing the display module 10 and the comparative display module 10-C to have different sizes. In the comparative display module 10-C, a distance a6 (hereinafter, referred to as a sixth distance) between the distal end of the lower substrate LPL and the rigid wiring board 210-C, a distance a7 (hereinafter, referred to as a seventh distance) between a distal end of the wiring board 210-C and the film connecting member CM-1, a width a8 (hereinafter, referred to as an eighth distance) of the film connecting member CM-1, and a width a9 (hereinafter, referred to as a ninth distance) of the wiring board 210-C in the second direction DR2, which are measured in the second direction DR2, may be distances measured from the lower outer part of the display panel 100. Here, the film connecting member CM-1 may substantially correspond to an area of the wiring board 210-C, in which the terminal part TM connected to the flexible film FP is disposed. Accordingly, the seventh distance a7 may correspond to a gap between the terminal part TM and the distal end of the wiring board 210-C, and the eighth distance a8 may substantially correspond to a length of the terminal part TM in the second direction DR2.

In contrast, according to the display module 10 according to an embodiment of the present disclosure, since the flexible film FP is omitted, the body part R1 of the wiring board 210, which is relatively rigid and may have the same configuration as the wiring board 210-C of the comparative display module 10-C, may correspond to the rigid wiring board 210-C of the comparative display module 10-C, and the protrusion part R2, which is relatively flexible, may correspond to the flexible film FP of the comparative display module 10-C. Accordingly, the sixth distance a6 may correspond to a gap between the lower substrate LPL and a distal end of the body part R1, and the ninth distance a9 may correspond to a width in the second direction DR2 of the wiring board 210 including the body part R1 and the protrusion part R2.

In the comparative display module 10-C, the flexible film FP should be connected to each of the display panel 100 and the wiring board 210-C and thus needs to be provided with size including a part that overlaps the display panel 100, a part that overlaps the wiring board 210-C, and a part that extends between the display panel and the wiring board 210-C. That is, the flexible film FP has a width including at least the fourth distance a4 to the eighth distance a8 in the second direction DR2.

In contrast, according to the display module 10 according to the present disclosure, the flexible film FP is omitted, a portion of the integrated wiring board 210 is formed as the protrusion part R2 for connection to the display panel 100, and thus size for connection to the body part R1 may be omitted. Thus, the seventh distance a7 and the eighth distance a8 overlapping the body part R1 may not be present in the display module 10 according to the present disclosure. Further, according to the display module 10 according to the present disclosure, the circuit board 200 is assembled without bending, the protrusion part R2 having the terminal part TM is formed integrally with the body part R1, and thus the sixth distance a6 for connection may be minimized. The sixth distance a6 may substantially correspond to a gap between the distal end of the lower substrate LPL and a distal end of the rigid board 210-C and R1. Accordingly, a distance a10 (hereinafter, referred to as a tenth distance) between a distal end of the wiring board 210 that is rigid and one end of the connection member CM may be relatively smaller. The wiring board 210 may be disposed closer to the distal end of the lower substrate LPL than the wiring board 210-C of the comparative display module 10-C.

When viewed from a rear surface of the display panel 100, a width of a rigid board 210-C and R2 in the second direction DR2 may be determined by a distance all (hereinafter, referred to as an 11^{th} distance) between the electronic component 220 and one end of the rigid board 210-C and R1, a width a12 (hereinafter, referred to as a 12^{th} distance) of the electronic component 220 in the second direction DR2, and a distance a13 (hereinafter, referred to as a 13^{th} distance) between the electronic component 220 and the other end of the rigid board 210-C or R2. According to the display module 10 according to the present disclosure, the flexible film FP is omitted, the seventh distance a7 and the eighth distance a8 overlapping with the body part R1 are not present, connection between the wiring board 210-C and 210 and the display panel 100 is made at the protrusion part R2, and thus the 11^{th} distance a11, which is a gap between the electronic component 220 and the distal end of the rigid board R1, may be reduced as compared to the 11^{th} distance a11 in the comparative display module 10-C.

When the wiring boards 210-C and 210 having the same size are provided in the comparative display module 10-C and the display module 10 according to the present disclosure, a difference or gap DSG may be measured between the distal end of the wiring board 210 of the display module 10 according to the present disclosure and the distal end of the wiring board 210-C of the comparative display module 10-C. The gap DSG may be about 10% to 30% of the ninth distance a9, but the present disclosure is not limited thereto.

Further, according to the display module 10 according to the present disclosure, the body part R1 and the protrusion part R2 are integrally formed, connection between the flexible film FP and the body part R1 is not required, and thus a wiring structure of the body part R1 may be relatively simplified as compared to the wiring structure of the wiring board 210-C of the comparative display module 10-C. Accordingly, a thickness of the body part R1 may be smaller than a thickness of the wiring board 210-C of the comparative display module 10-C. The flexible film FP is omitted, the protrusion part R2 and the display panel 100 are connected to each other, and thus the body part R1 may have a thickness reduced by about 10% to 20% as compared to the thickness of the existing wiring board 210-C. However, the present disclosure is not limited thereto.

According to the present disclosure, the display module 10 according to an embodiment of the present disclosure includes the circuit board 200 including the body part R1 and the protrusion part R2 that are integrated, and thus the display module 10 may have a reduced thickness and a reduced size of an outer part of the display panel 100. Further, in the display module 10, the width in the second direction DR2 of the protrusion part R2 connected to the display panel 100 may be minimized, a single printed circuit board may include both the protrusion part R2 connected to the display panel 100 and the body part R1 on which the electronic component 220, and thus costs for manufacturing the electronic device may be reduced, and the degree of freedom of design may be improved.

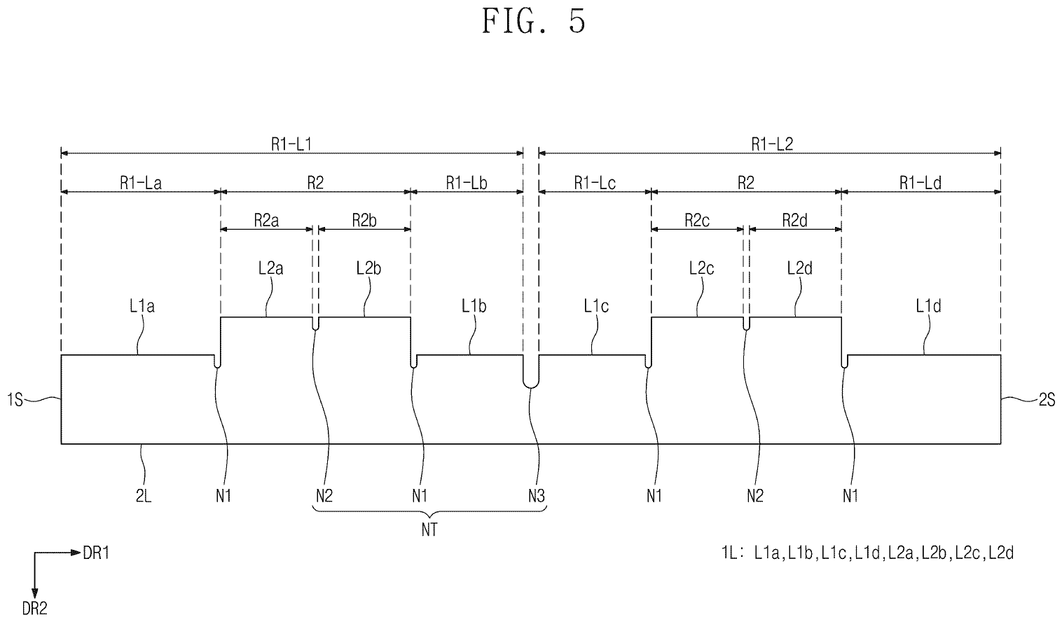

FIG. 5 is a plan view of a circuit board according to an embodiment of the present disclosure. In FIG. 5, for easy description and clarity of illustration, the electronic component is omitted, and only the wiring board is illustrated. Hereinafter, an embodiment in accordance with the present disclosure as shown in FIG. 5 is described.

The wiring board 210 may include an upper side 1L that extends in the first direction DR1 and faces the display panel 100 (see FIG. 2A), a lower side 2L that is opposite thereto, and a left side 1S and a right side 2S that extend in the second direction DR2 and are opposite to each other. As described above, the wiring board 210 may be divided into the body part R1 and the protrusion part R2. The body part R1 may be a quadrangular part including the lower side 2L, the left side 1S, and the right side 2S.

In an embodiment, the body part R1 may include a first sub-body portion R1-L1 and a second sub-body portion R1-L2 that are adjacent along the first direction DR1. A notch N3 may be between the first sub-body portion R1-L1 and the second sub-body portion R1-L2. Notches NT, including notch N3, on the upper side 1L of the wiring board 210 are described further below.

The protrusion part R2 may be a part that protrudes from the body part R1 toward the display panel 100. The protrusion part R2 may be a part of the wiring board 210, which includes the terminal part TM. The terminal part TM may be a part that electrically connects to the display panel 100. The terminal part TM may contact the connection member CM (see FIG. 3B) for electrical connection to the display panel 100. The terminal part TM may particularly connect to the pad parts PD1 and PD2 (see FIG. 3B) of the display panel 100 through the connection member CM.

In an embodiment, the protrusion part R2 may protrude from each of the first sub-body portion R1-L1 and the second sub-body portion R1-L2. The protrusion part R2 that protrudes from the first sub-body portion R1-L1 may include a first sub-protrusion portion R2a and a second sub-protrusion portion R2b that are adjacent along the first direction DR1. A notch N2 may be between the first sub-protrusion portion R2a and the second sub-protrusion portion R2b. The first sub-body portion R1-L1 may include a first portion R1-La and a second portion R1-Lb spaced apart from each other in the first direction DR1 with the protrusion part R2 interposed therebetween.

The protrusion part R2 that protrudes from the second sub-body portion R1-L2 may include a third sub-protrusion portion R2c and a fourth sub-protrusion portion R2d that are adjacent along the first direction DR1. Another notch N2 may be between the third sub-protrusion portion R2c and the fourth sub-protrusion portion R2d. The second sub-body portion R1-L2 may include a third portion R1-Lc and a fourth portion R1-Ld spaced apart from each other in the first direction DR1 with the protrusion part R2 interposed therebetween.

The circuit board 200 according to the embodiment of FIG. 5 may include the notches NT formed in the wiring board 210. The notches NT may be formed on the upper side 1L of the wiring board 210 and may be formed at boundaries between parts of the wiring board 210. The notches NT may include at least one of a first notch N1, the second notch N2, and the third notch N3.

The first notches N1 may be formed in areas of the first to fourth portions R1-La, R1-Lb, R1-Lc, and R1-Ld that are adjacent to the protrusion part R2. In an embodiment, the first notches N1 may be formed in an area of the first portion R1-La that is connected to a left side of the protrusion part R2 and an area of the second portion R1-Lb that is connected to a right side of the protrusion part R2. Further, the first notches N1 may be formed in an area of the third portion R1-Lc that is connected to the left side of the protrusion part R2 and an area of the fourth portion R1-Ld that is connected to the right side of the protrusion part R2. The first notches N1 may serve to partially cut off the physical connection between the body part R1 and the protrusion part R2. An upper side L1a of the first portion R1-La and an upper side L1b of the second portion R1-Lb may be spaced apart from the protrusion part R2 by the first notches N1. Likewise, an upper side L1c of the third portion R1-Lc and an upper side L1d of the fourth portion R1-Ld may be spaced apart from the protrusion part R2 by the first notches N1. Accordingly, when the protrusion part R2 is elongated or deformed in the first direction DR1, which a bonding process may cause, this elongation or deformation may be prevented from being transmitted to the body part R1, and deformation of the body part R1 may be reduced.

The second notches N2 may be formed inside the protrusion part R2. Each second notch N2 may be formed on an upper side of the protrusion part R2. An upper side L2a of the first sub-protrusion portion R2a and an upper side L2b of the second sub-protrusion portion R2b may be spaced apart from each other in the first direction DR1 with the second notch N2 interposed therebetween. Accordingly, elongation of the first sub-protrusion portion R2a, which may occur in the first direction DR1, and elongation of the second sub-protrusion portion R2b, which occurs in the first direction DR1, may be independent of each other. Further, the elongation of the protrusion part R2, which occurs in the first direction DR1, may be separated into the elongation of the first sub-protrusion portion R2a and the elongation of the second sub-protrusion portion R2b, and thus substantial deformation of the protrusion part R2 may be reduced.

Another second notch N2 may be at a border between the third sub-protrusion portion R2c and the fourth sub-protrusion portion R2d. An upper side L2c of the third sub-protrusion portion R2c and an upper side L2d of the fourth sub-protrusion portion R2d may be spaced apart from each other in the first direction DR1 with the second notch N2 interposed therebetween. Accordingly, elongation of the third sub-protrusion portion R2c, which occurs in the first direction DR1, and elongation of the fourth sub-protrusion portion R2d, which occurs in the first direction DR1, may be independent of each other. Further, the elongation of the protrusion part R2, which occurs in the first direction DR1, may be separated into the elongation of the third sub-protrusion portion R2c and the elongation of the fourth sub-protrusion portion R2d, and thus substantial deformation of the protrusion part R2 may be reduced.

Alternatively, for example, the third notch N3 may be formed between the sub-body portions R1-L1 and R1-L2. The third notch N3 may be formed in an area between the first sub-body portion R1-L1 and the second sub-body portion R1-L2 that are connected to each other. The third notch N3 may serve to separate an upper side of the body part R1. The upper side L1b of the second portion R1-Lb of the first sub-body portion R1-L1 and the upper side L1c of the third portion R1-Lc of the second sub-body portion R1-L2 may be spaced apart from each other in the first direction DR1 by the third notch N3. Accordingly, elongation of the first sub-body portion R1-L1, which occurs in the first direction DR1, and elongation of the second sub-body portion R1-L2, which occurs in the first direction DR1, may be independent of each other. Further, the elongation of the body part R1, which occurs in the first direction DR1, may be separated into the elongation of the first sub-body portion R1-L1 and the elongation of the second sub-body portion R1-L2, and thus substantial deformation of the body part R1 may be reduced.

The circuit board 200 according to an embodiment of the present disclosure may include at least one notch NT formed in the wiring board 210. The notch NT may be formed on the upper side 1L of the wiring board 210, which is connected to the display panel 100, and may be formed by removing at least a portion of the upper side 1L. FIG. 5 illustrates an embodiment in which each notch NT has a U shape in the plan view, but the present disclosure is not limited thereto, and the notch NT may be formed in various shapes such as a quadrangular shape, a V shape, a semicircular shape, and a semielliptical shape as long as the notch NT may spatially separate the upper sides of regions of the wiring board 210, and the present disclosure is not limited to the illustrated embodiment. Further, FIG. 5 illustrates four first notches N1, two second notches N2, and one third notch N3, but the numbers of the first to third notches N1, N2, and N3 are not limited to the illustrated embodiment. For example, only one type of the first to third notches N1, N2, and N3 may be present. In the circuit board 200 according to an embodiment of the present disclosure, at least one notch NT is formed in the wiring board 210, the amount of deformation for length deformation such as the elongation/contraction in the first direction DR1, which may occur during bonding of the wiring board 210 is dispersed, and thus concentration of local deformation may be prevented. Accordingly, the electronic device including the wiring board 210 having improved electrical reliability may be provided.

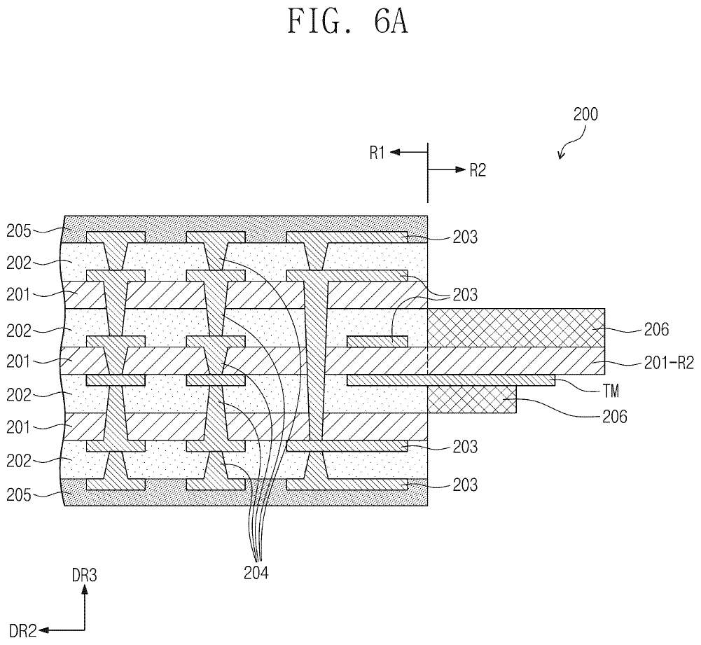

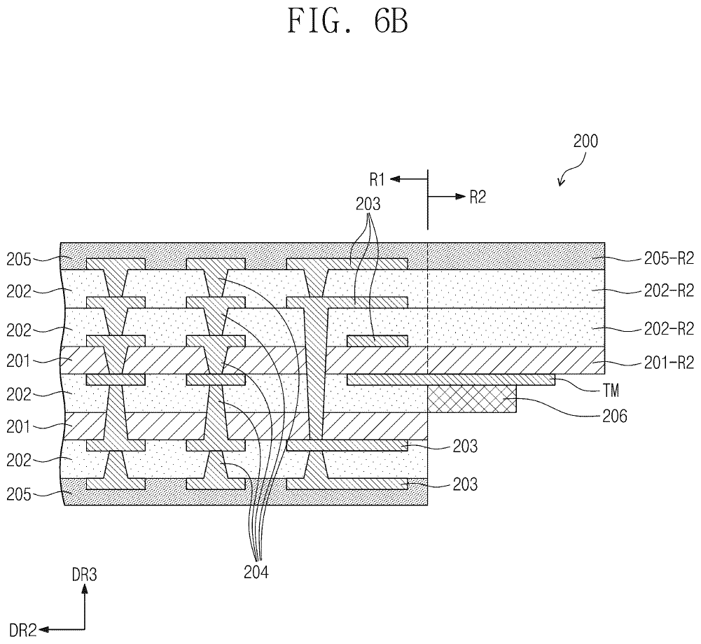

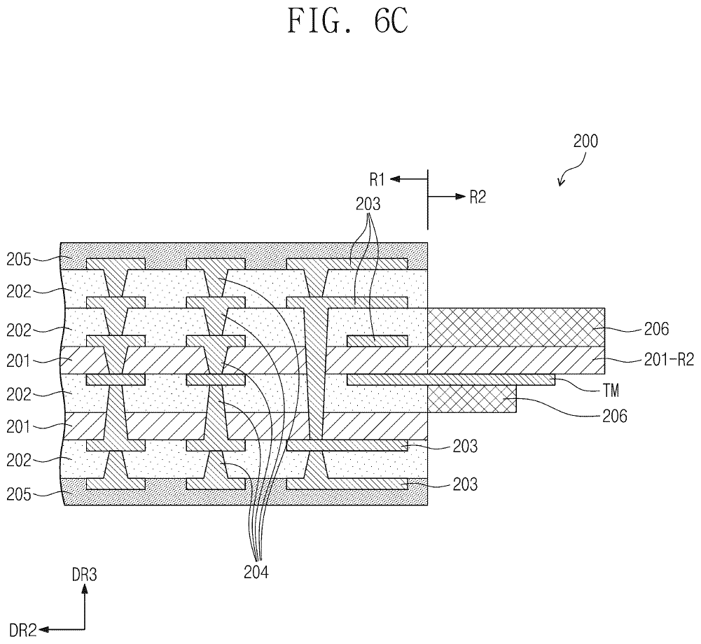

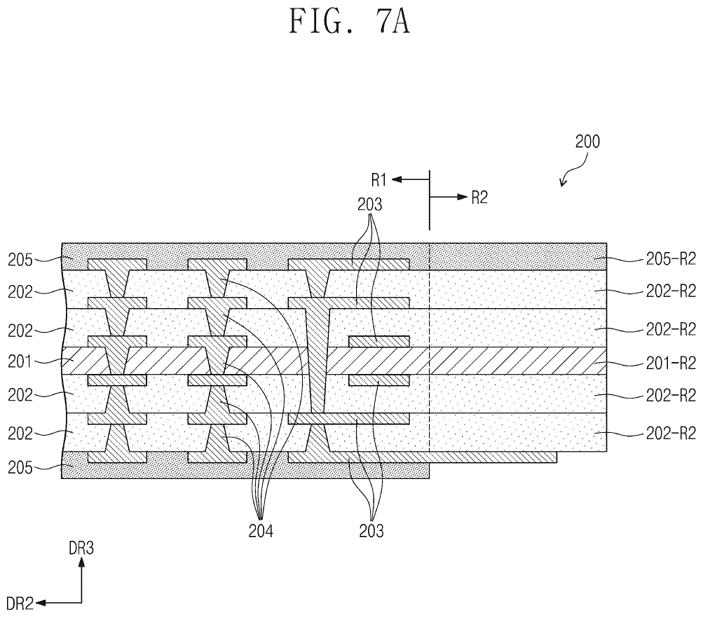

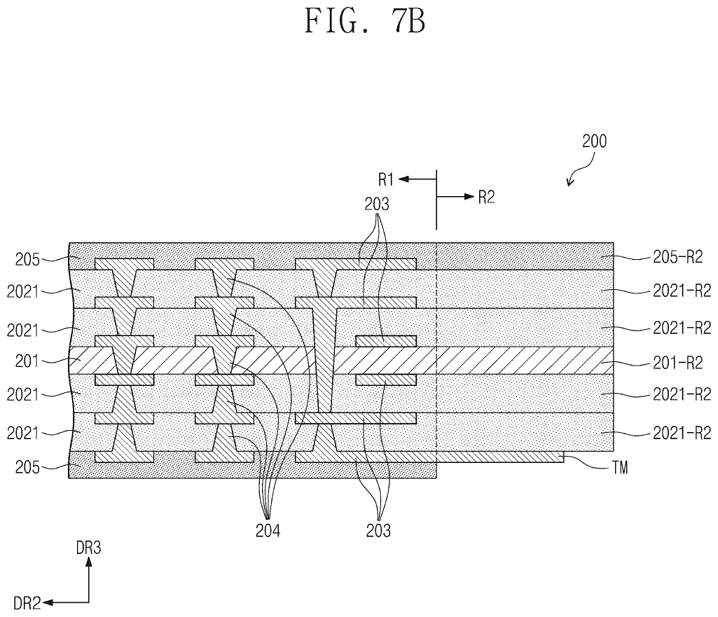

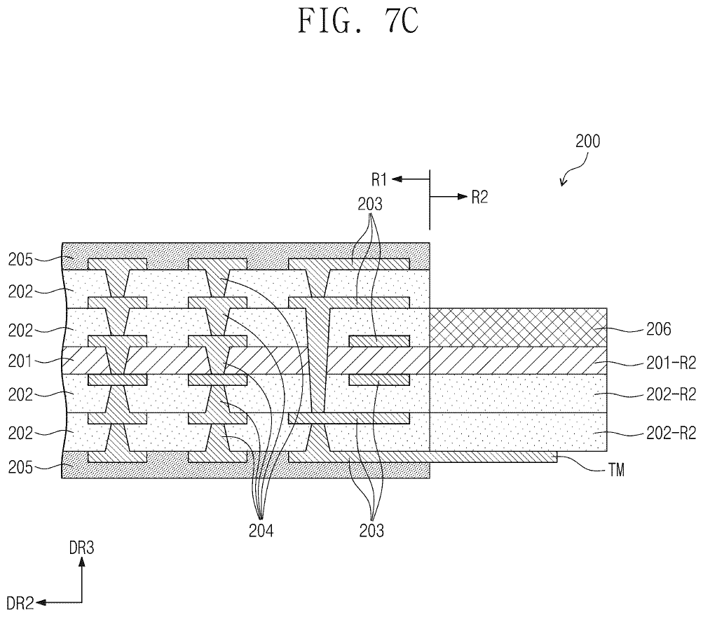

FIGS. 6A to 6C are cross-sectional views of the circuit board according to some embodiments of the present disclosure. FIGS. 7A to 7C are cross-sectional views of the circuit board according to some other embodiments of the present disclosure. FIGS. 6A to 7C are cross-sectional views along line I-I′ illustrated in FIG. 2. Hereinafter, some embodiments in accordance with the present disclosure are described with reference to FIGS. 6A to 7C.

Referring to FIGS. 6A to 7C, the body part R1 may include a plurality of layers. For example, the body part R1 may include a plurality of insulating layers 201 and 202, a plurality of wiring layers 203, a plurality of via layers 204, and a plurality of cover layers 205.

Each first insulating layer 201 and each second insulating layer 202 may have different elastic moduli. For example, the first insulating layers 201 may have a relatively lower elastic modulus than that of the second insulating layers 202. That is, each first insulating layer 201 may be a layer that has relatively rigid properties as compared to the second insulating layers 202. For example, the first insulating layers 201 may include polyimide, and the second insulating layers 202 may include a prepreg or an ABF, e.g., an Anisotropic Binderless Film. However, the present disclosure is not limited thereto, the first insulating layer 201 and the second insulating layer 202 may include materials such as a thermosetting resin, a thermoplastic resin, a glass fiber, or an inorganic filler, and various combinations of materials may be selected as long as a relationship in which the first insulating layer 201 has a lower elastic modulus than that of the second insulating layer 202 is satisfied.

The body part R1 of the circuit board 200 in the illustrated embodiments has a structure in which the first insulating layers 201 and the second insulating layers 202 are partially and alternately laminated, but the present disclosure is not limited thereto. The first insulating layers 201 and the second insulating layers 202 may be alternately stacked and laminated as a whole, or the body part R1 may have a structure including only the first insulating layers 201 or the second insulating layers 202 but the present disclosure is not limited to just these embodiments.

The wiring layers 203 may be arranged on the insulating layers 201 and 202. Each of the wiring layers 203 may be conductive. For example, each of the wiring layers 203 may include a metal. In detail, each of the wiring layers 203 may include copper, aluminum, silver, tin, gold, nickel, lead, titanium, or an alloy thereof. Each of the wiring layers 203 may be formed through a plating process and may include an electrolytic plating layer.

The via layers 204 electrically connect the wiring layers 203 adjacent to each other in a thickness direction, i.e., the third direction DR3. The via layers 204 may pass and extend through one or more of the insulating layers 201 and 202. The via layers 204 may completely fill an inside of a via hole passing through one or more of the insulating layers 201 and 202 or may be formed along wall surfaces of the via holes. Each of the via layers 204 may pass through at least one of the insulating layers 201 and 202. Some of the via layers 204 may pass through a plurality of layers among the insulating layers, may pass through only the first insulating layers 201, pass through only the second insulating layers 202, or pass through both first and second insulating layers 201 and 202, but the present disclosure is not limited to just these embodiments.

Each of the via layers 204 may be conductive. For example, each of the via layers 204 may include a metal. The via layers 204 may be formed of the same material as that of the wiring layers 203. However, the via layers 204 may instead be formed of a material different from that of the wiring layers 203, and the present disclosure is not limited to just these embodiments.

The cover layers 205 are disposed on upper and lower sides of the wiring board 210. The cover layers 205 may form an upper surface and a lower surface of the wiring board 210. The cover layers 205 may protect an internal component of the circuit board 200, specifically, the insulating layers 201 and 202, the wiring layers 203, and the via layers 204. The cover layers 205 may be formed of an insulating material. For example, the cover layers 205 may be an ABF containing a thermosetting resin and an inorganic filler or a solder resist layer. However, the cover layers 205 may be formed of various materials as long as the cover layers 205 may protect the internal component of the circuit board 200, such as a widely known photosensitive insulating layer, but the present disclosure is not limited to these embodiments. Further, the cover layer 205 may be formed of different materials or through different processes on an upper side and a lower side of the circuit board 200 or may be formed in the same manner, but the present disclosure is not limited to these embodiments.

The protrusion part R2 may have a thickness smaller than that of the body part R1. The protrusion part R2 has a shape integrated with the body part R1. That is, the protrusion part R2 may have a layer structure in which at least one layer among the layers constituting the body part R1 is omitted. For example, the protrusion part R2 may include at least one first insulating layer 201 and a single wiring layer 203. The wiring layer 203 of the protrusion part R2 may form the terminal part TM of the circuit board 200. The terminal part

TM may extend from any one wiring layer among the wiring layers 203 in the body part R1. According to the present disclosure, the protrusion part may only include a single wiring layer 203, and thus the number of insulating layers required for the protrusion part R2 may be reduced. Accordingly, the thickness of the protrusion part R2 may be reduced as compared to the body part R1, and thus the protrusion part R2 may have a higher ductility than that of the body part R1. As the ductility of the protrusion part R2 in which the terminal part TM is disposed increases, stress may be reduced when the display panel 100 and the circuit board 200 are connected to each other, and stable electrical connection may be achieved.

According to the present disclosure, a layer structure constituting the body part R1 and the protrusion part R2 may be provided in different embodiments. For example, referring to FIG. 6A, the body part R1 may include three first insulating layers 201, four second insulating layers 202, and six wiring layers 203. The circuit board 200 may correspond to a structure including two copper clad layers (CCLs). In this regard, the protrusion part R2 may include a single first insulating layer 201-R2 (hereinafter, referred to as a protruding first insulating layer) and the terminal part TM. The protruding first insulating layer 201-R2 and the terminal part TM may extend from the body part R1 and may be integrated with the body part R1. Among the three first insulating layers 201 arranged in the body part R1, only one first insulating layer 201 may extend to the protrusion part R2 as the protruding first insulating layer 201-R2, and the remaining two first insulating layers 201 may be removed from the protrusion part R2. Accordingly, two etching operations (e.g., laser etching operations) for removing the two first insulating layers 201 may be included in a process of manufacturing the circuit board 200. Accordingly, the protrusion part R2 that is thinner and more flexible than the body part R1 may be formed.

One or more protective layers 206 may be added to an upper surface and/or a lower surface of the protrusion part R2. The protective layer 206 may support one surface of the protruding first insulating layer 201-R2, prevent excessive exposure of the terminal part TM, protect the terminal part TM from external moisture or contamination, and prevent electrical short-circuiting with external components.

FIG. 6B shows an embodiment in which the body part R1 may include two first insulating layers 201, four second insulating layers 202, and six wiring layers 203. That is, the body part R1 may have a layer structure in which one first insulating layer 201 is omitted as compared to the body part R1 illustrated in FIG. 6A. The circuit board 200 illustrated in FIG. 6B may correspond to a structure including one CCL. The first insulating layer 201 may be relatively thick as compared to the second insulating layer 202 and may be provided in the form of a film. Thus, the body part R1 illustrated in FIG. 6B may have a reduced thickness as compared to the body part R1 illustrated in FIG. 6A, and the number of etching operations (laser etching operations) for removing a portion of the first insulating layer 201 to form the protrusion part R2 may be reduced. Thus, a process may be simplified, and process costs may be reduced.

The protrusion part R2 of FIG. 6B may be formed by removing the one first insulating layer 201, the two second insulating layers 202, and the one cover layer 205 of the body part R1. That is, the protrusion part R2 may include the one first insulating layer 201-R2 (hereinafter, referred to as the protruding first insulating layer), two second insulating layers 202-R2 (hereinafter, referred to as protruding second insulating layers), one cover layer 205-R2 (hereinafter, a protruding cover layer), and the terminal part TM. The protruding first insulating layer 201-R2, the protruding second insulating layer 202-R2, the protruding cover layer 205-R2, and the terminal part TM may extend from the body part R1 and may be integrated with the body part R1. According to the present disclosure, the protruding second insulating layer 202-R2 and the protruding cover layer 205-R2 may support the protruding first insulating layer 201-R2, and the number of protective layers 206 required for the protrusion part R2 may be reduced as compared to the circuit board 200 illustrated in FIG. 6A.

FIG. 6C shows an embodiment in which the body part R1 may have the same layer structure as that of FIG. 6B, and the protrusion part R2 may have the same layer structure as that of the protrusion part R2 illustrated in FIG. 6A. In the protrusion part R2 illustrated in FIG. 6C, two protective layers 206 may be required since the protruding second insulating layers 202-R2 are removed as compared to the protrusion part R2 illustrated in FIG. 6B.

FIG. 7A shows an embodiment in which the circuit board 200 may include the protrusion part R2 from which only the one cover layer 205 among the components of the body part R1 is removed. The protrusion part R2 may include the protruding first insulating layer 201-R2 in which the first insulating layer 201 of the body part R1 extends, the protruding second insulating layers 202-R2 in which the second insulating layers 202 of the body part R1 extend, and the protruding cover layer 205-R2 in which one of the cover layers 205 of the body part R1 extends. The wiring layers 203 in the embodiment of FIG. 7A may be patterned so that only a bottom wiring layer 203 extends into the protrusion part R2, and therefore none of the wiring layers need to be subsequently removed to form the protrusion part R2. The circuit board 200 according to the embodiment of FIG. 7A includes the protrusion part R2 has a structure that is substantially similar to the body part R1, and thus the protrusion part R2 may be thicker than the circuit boards 200 illustrated in FIG. 6A to 6C. Accordingly, a shrinkage stress of the protrusion part R2 may be reduced. The amount of deformation of the protrusion part R2 due to degradation or the like may be reduced during a process for connection to the display panel 100, and thus misalignment due to the elongation may be prevented. Thus, a more stable electrical connection process may be achieved.

FIG. 7B shows an embodiment in which the circuit board 200 may include rigid second insulating layers 2021. The second insulating layers 2021 may be formed of a prepreg that is more rigid than the second insulating layer 202 illustrated in FIG. 7A. The protrusion part R2 may include protruding rigid second insulating layers 2021-R2 that are formed to extend from the body part R1. The circuit board 200 according to the embodiment of FIG. 7B includes rigid insulating layers 2021, and thus the protrusion part R2 may have high rigidity. Accordingly, dimensional stability of the circuit board 200 may be improved, the amount of deformation due to the degradation in the process for connection to the display panel 100 may be reduced, and thus the misalignment due to the elongation may be prevented. Thus, a more stable electrical connection process may be achieved.

FIG. 7C shows an embodiment in which the circuit board 200 may include the body part R1 having the same layer structure as that in FIG. 7A and the protrusion part R2 having a smaller thickness than that of the protrusion part R2 in FIG. 7A. The protrusion part R2 may include the protruding second insulating layers 202-R2 interposed between the terminal part TM and the protruding first insulating layer 201-R2. Accordingly, the circuit board 200 of FIG. 7D may have a reduced thickness and reduced process/material costs when compared to the circuit board 200 illustrated in FIG. 7A.

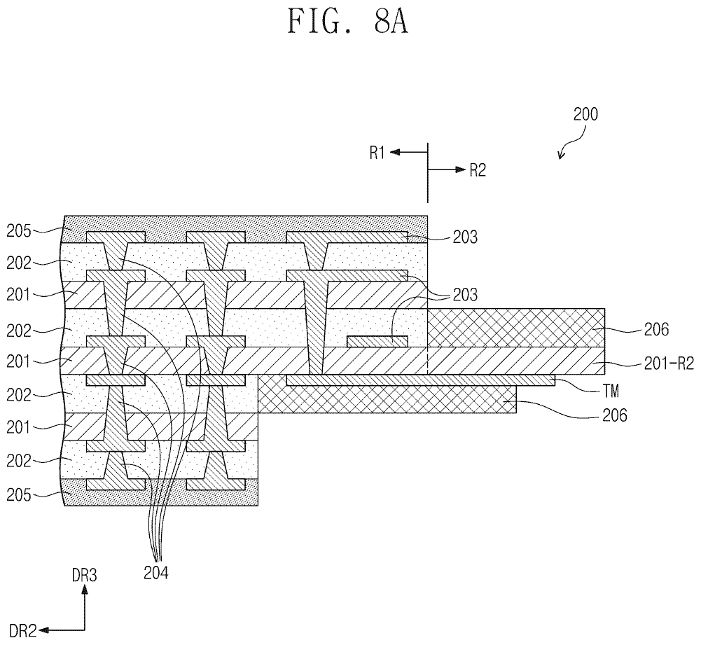

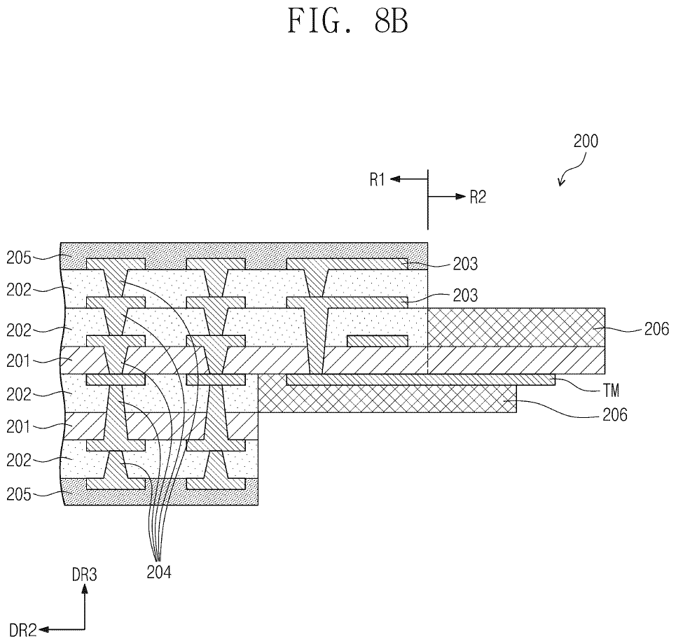

FIGS. 8A and 8B are cross-sectional views of the circuit board 200 according to some embodiments of the present disclosure. For easy description, FIGS. 8A and 8B illustrate an area corresponding to the area illustrated in FIGS. 6A and 6B. Hereinafter, embodiments are described with reference to FIGS. 8A and 8B. The same reference numerals are assigned to the same components as those described with reference to FIGS. 1A to 7C, and a duplicated description thereof is omitted below.

Referring to FIGS. 8A and 8B, at least a portion of the body part R1 may be removed. FIG. 8A shows an embodiment of the circuit board 200 that may be formed by removing a portion of the body part R1 of the circuit board 200 illustrated in FIG. 6A. FIG. 8B shows an embodiment of the circuit board 200 that may be formed by removing a portion of the circuit board 200 illustrated in FIG. 6C.

The protective layer 206 disposed in the protrusion part R2 may extend to a partial area of the body part R1 to prevent exposure of a wiring layer that has a shape integrated with the terminal part TM. A portion of a bottom surface of the body part R1, on which the terminal part TM is formed, may be removed. Accordingly, interference between the body part R1 and the distal end of the display panel 100 (see FIG. 2B) connected to the terminal part TM may be prevented. In the circuit board 200 of FIG. 8A or 8B, even when the length of the protrusion part R2 is not increased, a step portion that is a recessed area is provided in the body part R1, and thus contact between the distal end of the display panel 100 and the body part R1 may be prevented.

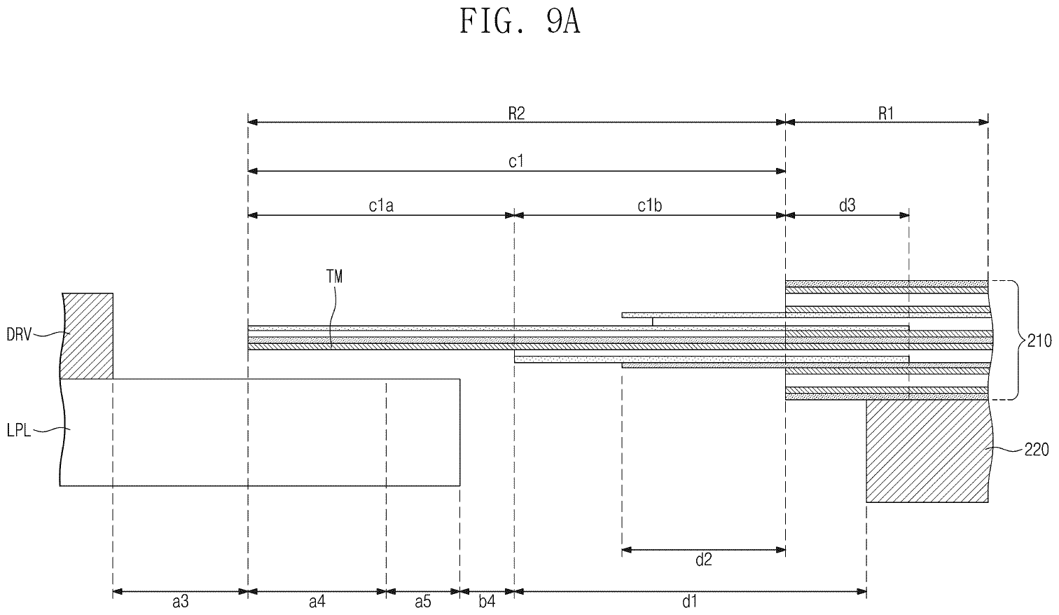

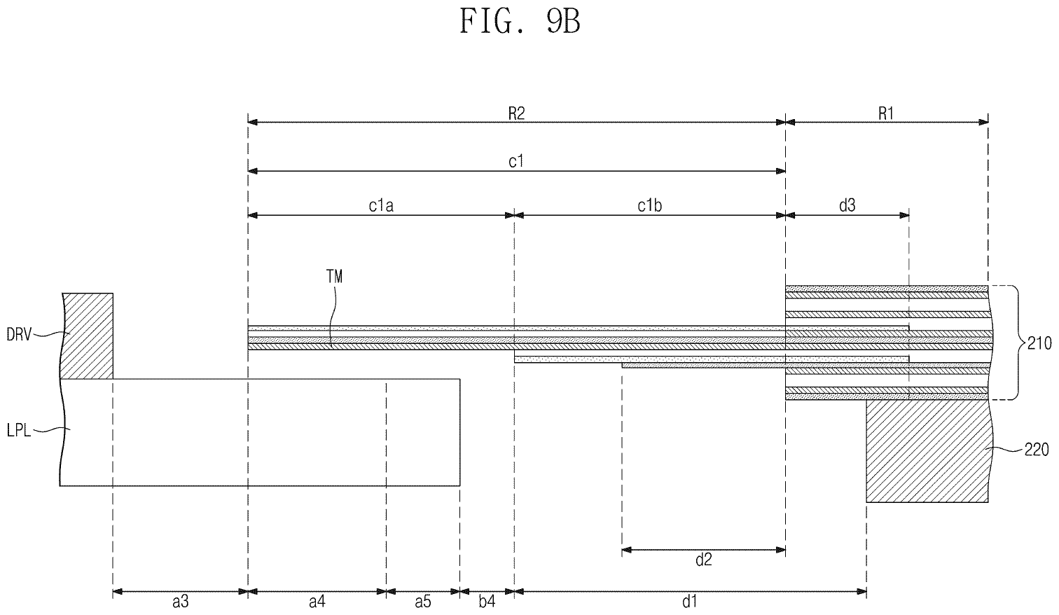

FIGS. 9A and 9B are cross-sectional views of display modules according to some embodiments of the present disclosure. For easy description, FIGS. 9A and 9B are cross-sectional views illustrating an operation connecting the display panel 100 and the circuit board 200 and may illustrate layer configurations of the display panel 100 or the circuit board 200. Among layer configurations of the wiring board 210, the wiring layers are shaded with hatching in FIGS. 9A and 9B. Hereinafter, some embodiments of the present disclosure are described with reference to FIGS. 9A and 9B. The same reference numerals are assigned to the same components as those described with reference to FIGS. 1A to 8B, and a duplicated description thereof may be omitted below.

Referring to FIGS. 9A and 9B, a single hatched or wiring layer is in the protrusion part R2, and the body part R1 includes a plurality of hatched or wiring layers. That is, the protrusion part R2 includes a single wiring layer, and the body part R1 includes a plurality of wiring layers. The wiring layer in the protrusion part R2 may be an extension of one of the wiring layers of the body part R1. The wiring layer included in the protrusion part R2 may provide the terminal part TM of the wiring board 210.

A protruding section c1 of the protrusion part R2 may include a first section c1a and a second section c1b. In the first section c1a, the wiring layer included in the protrusion part R2 may be exposed and form the terminal part TM. In the second section c1b, the wiring layer included in the protrusion part R2 may be covered by another layer such as an insulating layer and may not be exposed to the outside.

In the first section c1a of the protrusion part R2, the terminal part TM may be exposed for connection to the display panel 100. A distal end of the insulating layer, through which the terminal part TM is exposed and which covers the second section c1b, may extend to a boundary between the first section c1a and the second section c1b and may be spaced a predetermined distance d1 from the electronic component 220 and a distance b1 from the lower substrate LPL when the protrusion part R2 is connected to the lower substrate LPL. According to the present disclosure, the terminal part TM is at a position spaced apart from the electronic component 220 by the predetermined distance d1, so that a sufficient separation distance between the electronic component 220 and the lower substrate LPL may be secured. Accordingly, when the display panel 100 and the terminal part TM are connected to each other, interference (e.g., physical collision or the like) of the electronic component 220 with the lower substrate LPL may be prevented, and thus the stability of connection between the display panel 100 and the circuit board 200 may be improved.

As described above, at least some of the plurality of layers in the body part R1 may not be in the protrusion part R2. Accordingly, the protrusion part R2 has a relatively smaller thickness than that of the body part R1. Among the plurality of wiring layers constituting the body part R1, the remaining wiring layers except for one wiring layer forming the terminal part TM do not extend to the protrusion part R2. Accordingly, distal ends of the remaining wiring layers may be at or adjacent to a boundary between the body part R1 and the protrusion part R2.

Some of the plurality of insulating layers in the protrusion part R2 may extend only to a partial section d3 of the body part R1. Accordingly, some of the plurality of insulating layers constituting the protrusion part R2 may be present only in the partial sections d3 and may not be present in the remaining areas of the body part R1.

Upper/lower surfaces of the first section c1a may be flat surfaces, and the second section c1b may have at least one step on an upper surface or a lower surface. That is, the first section c1a may have a constant thickness, and the second section c1b may include at least two areas having different thicknesses. The step formed in the second section c1b may be formed between the insulating layers by removing some of the insulating layers that cover the wiring layer of the protrusion part R2. Accordingly, the partial section d2 of the second section C1b may have a greater thickness. That is, the second section C1b may further include a predetermined stepped portion d2.

The stepped portion d2 may be provided in various forms. For example, referring to FIG. 9A, the stepped portion d2 may be formed on each of an upper surface and a lower surface of the second section c1b. Alternatively, referring to FIG. 9B, the stepped portion d2 may be formed only on the lower surface of the second section c1b. The circuit board 200 according to an embodiment of the present disclosure may include the protrusion part R2 including a single wiring layer constituting the terminal part TM, and the protrusion part R2 may include the second section c1b through which the terminal part TM is covered and not exposed. The second section c1b may include the stepped portion d2 and may be provided in various shapes, but the present disclosure is not limited to just these embodiments.

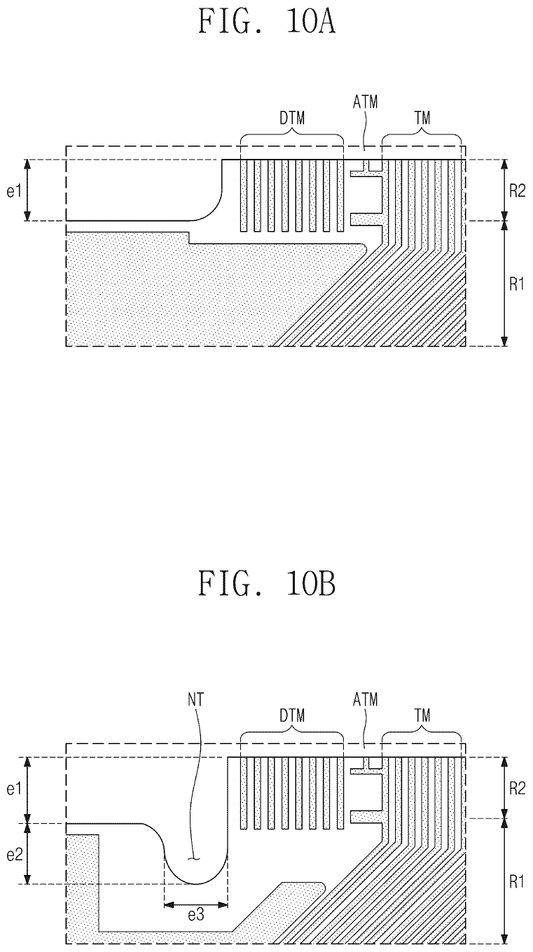

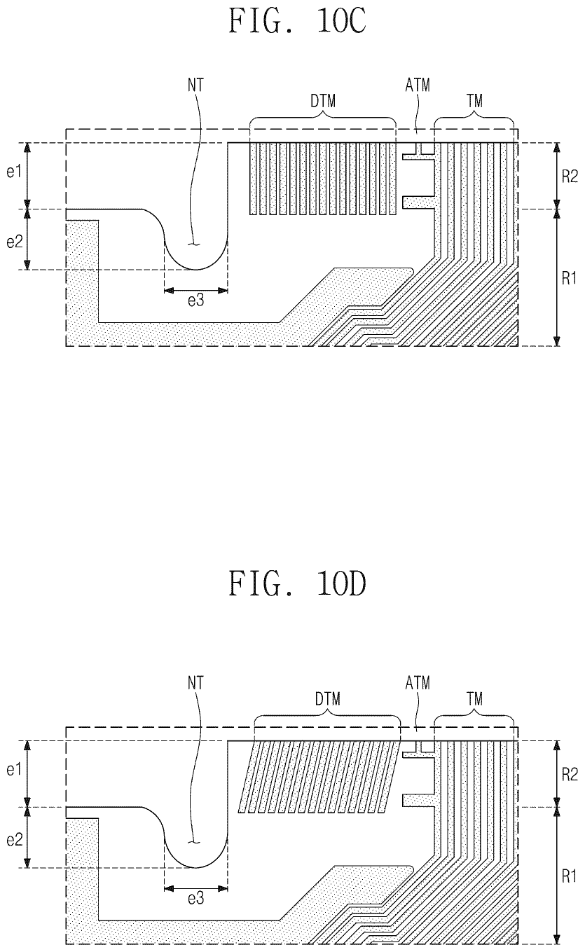

FIGS. 10A to 10D are plan views illustrating a portion of the circuit board in accordance with some embodiments of the present disclosure. FIGS. 10A to 10D show examples in which a size of the protrusion part R2, the terminal part TM, and an alignment mark ATM are the same. Hereinafter, some embodiments of the present disclosure are described with reference to FIGS. 10A to 10D.

Referring to FIG. 10A, the protrusion part R2 protrudes from the body part R1. In an embodiment, the protrusion part R2 may have a width el in the illustrated section. In the embodiment of FIG. 10A, no notch may be formed. The alignment mark ATM and a dummy terminal part DTM in addition to the terminal part TM may be further arranged in the protrusion part R2. FIG. 10A shows an embodiment in which the alignment mark ATM has an integral shape connected to the terminal part TM, but the present disclosure is not limited thereto, and a position and shape of the alignment mark ATM may be variously changed as long as the alignment mark ATM may be used for alignment between the circuit board 200 and the display panel 100. The dummy terminal part DTM may be disposed to be spaced apart from the terminal part TM. The dummy terminal part DTM may include a plurality of dummy terminal parts DTM and may be electrically insulated from the terminal part TM.

FIG. 10B shows an embodiment of the circuit board 200 that includes a notch NT. The notch NT may be in an area of the body part R1 is adjacent to the protrusion part R2. That is, FIG. 10B shows an embodiment in which the notch NT is the first notch N1 (see FIG. 5), but the present disclosure is not limited thereto. The notch NT may have a depth e2 defined in the second direction DR2 and a width e3 defined in the first direction DR1. According to an aspect of the present disclosure, as the notch NT is included, the design of the second section c1b may be easily performed, and thus interference between the electronic component 220 and the display panel 100 may be prevented without increasing a size of the wiring board 210.

FIG. 10C shows an embodiment of the circuit board 200 with a different number of dummy terminal parts DTM. FIG. 10C illustrates an embodiment having a greater number of dummy terminal parts DTM than does the embodiment illustrated in FIG. 10B. As the number of dummy terminal parts DTM is increased, a distance by which the terminal part TM is spaced apart from a left distal end of the protrusion part R2 may be increased. During bonding, a shrinkage stress may be relatively large at an edge of the protrusion part R2. Accordingly, even when the circuit board 200 and the display panel 100 are peeled off from each other due to the elongation/contraction during a bonding process, most of a shrinkage stress is applied to the dummy terminal parts DTM, and the shrinkage stress may not be transmitted to the terminal part TM that is spaced far apart from the distal end of the protrusion part R2. Accordingly, occurrence of electrical connection defects may be reduced.

The wiring layer may be easily designed such that, as the number of dummy terminal parts DTM increases, the terminal part TM is spaced further apart from the notch NT in the first direction DR1, and accordingly, the electronic component 220 is disposed further away in the second direction DR2. Thus, occurrence of a collision between the electronic component 220 and the display panel 100 may be prevented.

FIG. 10D shows an embodiment of the circuit board 200 in which the dummy terminal part DTM may have a shape inclined relative to the first direction DR1 and the second direction DR2. FIG. 10D thus illustrates that the dummy terminal part DTM may have a different shape or orientation from the terminal part TM, but the present disclosure is not limited thereto, and the terminal part TM may also have an inclined shape.

An inclined direction of the dummy terminal part DTM may be a direction for which a distance from the terminal part TM increases toward the body part R1. Accordingly, as the dummy terminal part DTM has an inclined shape, a size of an area occupied by the dummy terminal parts DTM may be increased as compared to the embodiment of FIG. 10C if the same number and spacing of dummy terminal parts DTM is used, and density of the dummy terminal parts DTM in an area adjacent to the terminal part TM may be reduced. Accordingly, the influence of the shrinkage stress applied to the terminal part TM may be reduced, and occurrence of electrical connection defects may be reduced.

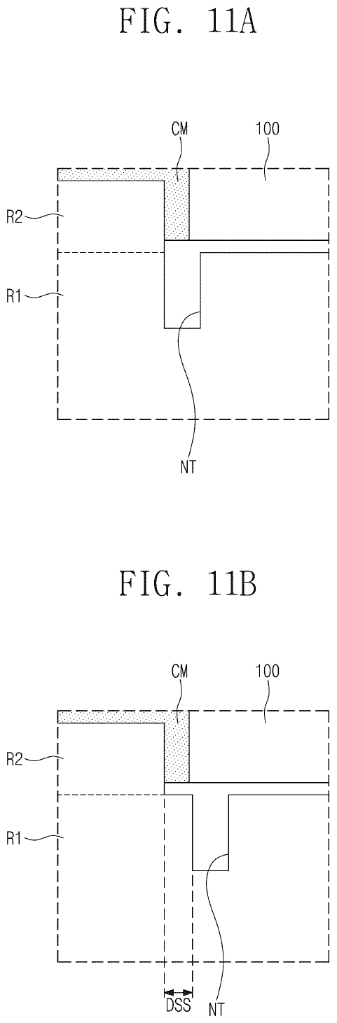

FIGS. 11A and 11B are plan views illustrating partial areas of the display module according to an embodiment of the present disclosure. For easy description, FIGS. 11A and 11B illustrate the same area and illustrate an area in which the notch NT is formed. Hereinafter, embodiments of the present disclosure are described with reference to FIGS. 11A and 11B.

As illustrated in FIG. 11A, in the display module 10 according to an embodiment of the present disclosure, the notch NT may be formed on an upper side of the body part R1, which faces the display panel 100, and may be formed in contact with the protrusion part R2.

Alternatively, as illustrated in FIG. 11B, the notch NT may be formed at a position spaced a predetermined distance DSS from the protrusion part R2. In this case, the notch NT may serve to spatially separate from each other portions of an edge of the body part R1. That is, the distance DSS according to an embodiment may be designed to be 0 (zero) or a predetermined numerical value. The distance DSS may be designed to various numerical values as long as the shrinkage stress of the protrusion part R2 is in a range that does not affect the body part R1, but embodiments of the present disclosure are not limited to these examples.

An electronic device according to an embodiment of the present disclosure may include the circuit board in which at least one notch is defined. The notch may be defined on a lateral side of the wiring board, which faces the display panel, and may be formed to be recessed from the display panel by a predetermined depth. The notch may serve to spatially separate the wiring board extending in the first direction DR1 into predetermined sections. Accordingly, the shrinkage stress due to the elongation or the like occurring during the bonding may be prevented from being transmitted in the first direction DR1. Accordingly, electrical reliability and process reliability of the electronic device may be improved.

Further, according to an aspect of the present disclosure, the protrusion part for connection to the display panel may be provided by removing some layers of the rigid circuit board. Thus, a separate wiring film such as the flexible film may be omitted, and thus material costs may be reduced, process costs may be reduced, and process time may be shortened. Further, a bezel of the electronic device may be reduced in size and a thickness of the bezel may be reduced.

According to an aspect of the present disclosure, electrical connection defects due to deformation of a circuit board, which may occur during a bonding process, may be improved.

Further, according to an aspect of the present disclosure, process costs may be reduced.

Further, according to an aspect of the present disclosure, an electronic device having a bezel with reduced size or thickness may be provided.

Although the description has been made above with reference to some embodiments of the present disclosure, it may be understood that those skilled in the art or those having ordinary knowledge in the art may variously modify and change the disclosed embodiments without departing from the spirit and technical scope of the present disclosure described in the appended claims. Thus, the technical scope of the present disclosure is not limited to the detailed description of the specification but should be defined by the appended claims.

What is claimed is:

1. An electronic device comprising:
a display panel including pads arranged along a first direction; and
a circuit board facing the display panel in a second direction intersecting the first direction and including a wiring board electrically connected to the pads and an electronic component mounted on the wiring board,
wherein the wiring board includes:
a body part which has a first thickness and on which the electronic component is mounted; and
a protrusion part that has a second thickness smaller than the first thickness and that protrudes from the body part toward the display panel, of which at least a portion overlaps the display panel, and which provides a terminal part connected to the pads, and
wherein at least one notch is defined on a side of the wiring board facing the display panel.

2. The electronic device of claim 1, wherein the notch is defined in an area adjacent to the protrusion part on a side of the body part facing the display panel.

3. The electronic device of claim 1, wherein the notch is defined on a side of the protrusion part facing the display panel.

4. The electronic device of claim 1, wherein the protrusion part a plurality of separate protrusion parts space along the first direction, and
wherein the notch is defined between the separate protrusion parts on a side of the body part facing the display panel.

5. The electronic device of claim 1, wherein the body part includes:
two cover layers having insulating properties;
at least one first insulating layer disposed between the two cover layers;
at least one second insulating layer disposed between the two cover layers and being more flexible than the first insulating layer;
at least one wiring layer disposed between the two cover layers and being conductive; and
a via layer passing through at least one of the first insulating layer and the second insulating layer and configured to electrically connect the at least one wiring layer and the electronic component and the terminal part, and
wherein the protrusion part has a shape integrated with at least one of the components of the body part.

6. The electronic device of claim 5, wherein the protrusion part includes a single wiring layer, and
wherein the single wiring layer extends from one of the wiring layers of the body part.

7. The electronic device of claim 5, wherein the at least one first insulating layer includes a film.

8. The electronic device of claim 7, wherein the at least one second insulating layer includes a prepreg.

9. The electronic device of claim 1, wherein the protrusion part further includes a step portion having a thickness that is smaller than the first thickness and different from the second thickness, and
wherein the step portion is disposed between the body part and a portion having the first thickness in the second direction.

10. The electronic device of claim 9, wherein the step portion has a shape integrated with the portion having the first thickness.

11. The electronic device of claim 1, wherein the circuit board further includes a dummy terminal part disposed in the protrusion part and electrically insulated from the terminal part, and
wherein the dummy terminal part is disposed closer to an outer side of the protrusion part than is the terminal part.

12. The electronic device of claim 11, wherein the dummy terminal part has a shape that is inclined relative to a shape of the terminal part.

13. The electronic device of claim 1, further comprising:
a case providing a space configured to accommodate the circuit board,
wherein the space is provided in the second direction with respect to the display panel.

14. An electronic device comprising:
a display panel including pads arranged along a first direction; and
a circuit board facing the display panel in a second direction intersecting the first direction and including a wiring board including a terminal part connected to the pads and an electronic component mounted on the wiring board,
wherein the wiring board includes:
a body part including a plurality of wiring layers, at least one of the wiring layers being connected to the electronic component; and
a protrusion part having a shape integrated with the body part and including a single wiring layer extending from any one of the wiring layers in the body part, and
wherein a first notch recessed in a direction away from the display panel between the body part and the protrusion part is defined on a side of the wiring board that faces the display panel.

15. The electronic device of claim 14, wherein the protrusion part includes:
a first portion having a first thickness; and
a second portion having a thickness greater than the first portion and disposed between the first portion and the body part in the second direction, and
wherein the first portion has a shape integrated with at least a portion of the second portion.

16. The electronic device of claim 15, wherein a length of the second portion in the second direction corresponds to a recessed depth of the first notch.

17. The electronic device of claim 15, wherein the circuit board further includes a dummy terminal part disposed in the protrusion part and electrically insulated from the terminal part, and
wherein the dummy terminal part is disposed between the first notch and the terminal part.

18. The electronic device of claim 17, wherein the terminal part extends in a direction inclined in the first direction and the second direction.

19. The electronic device of claim 14, wherein the circuit board further includes a second notch defined on a side of the protrusion part that faces the display panel.

20. The electronic device of claim 19, wherein the protrusion part includes a plurality of separate protrusion parts arranged along in the first direction, and
wherein the circuit board further includes a notch defined in the body part and disposed between the plurality of separate protrusion parts.

21. The electronic device of claim 14, wherein the electronic device further comprises:
an upper cover on the display panel; and
a lower cover coupled to the upper cover, and
wherein the display panel and the circuit board are accommodated between the upper cover and the lower cover.
